(19) United States
(12) Patent Application Publication
(10) Pub. No.: US 2021/0399164 A1
(43) Pub. Date: Dec. 23, 2021

(54) METHOD OF MANUFACTURING A RED LIGHT-EMITTING CHIP CARRYING STRUCTURE

(71) Applicant: ASTI GLOBAL INC., TAIWAN, Taichung City (TW)

(72) Inventors: CHIEN-SHOU LIAO, New Taipei City (TW); TE-FU CHANG, Taichung City (TW)

(21) Appl. No.: 17/351,258

(22) Filed: Jun. 18, 2021

(30) Foreign Application Priority Data
Jun. 19, 2020 (TW) 109120918

(51) Int. Cl. H01L 33/00; H01L 21/66

(52) U.S. Cl. CPC H01L 33/0093; H01L 2933/0066; H01L 22/12

(57) ABSTRACT

A method of manufacturing a red light-emitting chip carrying structure is provided. The method includes providing a red LED wafer including a wafer base, a plurality of porous connection layers, and a plurality of red LED chips; placing the red LED chips on a chip carrying substrate; projecting a laser light beam onto the porous connection layers or the chip carrying substrate; and then removing the wafer base and a removal part of each of the porous connection layers so as to leave a residual part of each of the porous connection layers on a corresponding one of the red LED chips. Therefore, the red LED chips can be transferred from the red LED wafer to a chip adhesive layer of the chip carrying substrate or a plurality of conductive soldering materials on the chip carrying substrate.

### CROSS-REFERENCE TO RELATED PATENT APPLICATION

This application claims the benefit of priority to Taiwan Patent Application No. 109120918, filed on Jun. 19, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method of manufacturing a chip carrying structure, and more particularly to a method of manufacturing a red light-emitting chip carrying structure.

### BACKGROUND OF THE DISCLOSURE

In the related art, a light-emitting diode (LED) chip can be transferred from a carrier to a circuit by a nozzle, but the method for transferring the LED chip still has room for improvement.

### SUMMARY OF THE DISCLOSURE

In response to the above-referenced technical inadequacy, the present disclosure provides a method of manufacturing a red light-emitting chip carrying structure.

In one aspect, the present disclosure provides a method of manufacturing a red light-emitting chip carrying structure, which includes: providing a red light-emitting diode (LED) wafer including a wafer base, a plurality of porous connection layers disposed on the wafer base, and a plurality of red LED chips respectively disposed on the porous connection layers; placing the red LED chips on a chip carrying substrate; projecting a laser light beam onto the porous connection layers or the chip carrying substrate; and then removing the wafer base and a removal part of each of the porous connection layers so as to leave a residual part of each of the porous connection layers on a corresponding one of the red LED chips.

In certain embodiments, the step of projecting the laser light beam onto the porous connection layers or the chip carrying substrate further includes: detecting a position of each of the porous connection layers so as to obtain position information of each of the porous connection layers; and then projecting the laser light beam onto the porous connection layer according to the position information of the porous connection layer so as to decrease a bonding strength of the porous connection layer between the wafer base and the red LED chip.

In certain embodiments, the step of projecting the laser light beam onto the porous connection layers or the chip carrying substrate further includes: detecting a position of each of a plurality of conductive soldering materials so as to obtain position information of each of the conductive soldering materials; and then projecting the laser light beam onto the conductive soldering material according to the position information of the conductive soldering material so as to increase a bonding strength between the red LED chip and the conductive soldering material.

In certain embodiments, the step of projecting the laser light beam onto the porous connection layers or the chip carrying substrate further includes: detecting a position of each of a plurality of conductive soldering materials so as to obtain position information of each of the conductive soldering materials; projecting the laser light beam onto the conductive soldering material according to the position information of the conductive soldering material so as to increase a bonding strength between the red LED chip and the conductive soldering material; detecting a position of each of the porous connection layers so as to obtain position information of each of the porous connection layers; and then projecting the laser light beam onto the porous connection layer according to the position information of the porous connection layer so as to decrease a bonding strength of the porous connection layer between the wafer base and the red LED chip.

In certain embodiments, after the step of removing the wafer base and the removal part of each of the porous connection layers, the method further includes: removing the residual part of each of the porous connection layers on the corresponding one of the red LED chips.

Therefore, by virtue of “placing the red LED chips on a chip carrying substrate” and “removing the wafer base and a removal part of each of the porous connection layers so as to leave a residual part of each of the porous connection layers on a corresponding one of the red LED chips”, the red LED chips can be transferred from the red LED wafer to a chip adhesive layer of the chip carrying substrate or a plurality of conductive soldering materials on the chip carrying substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method of manufacturing a red light-emitting chip carrying structure according to the present disclosure;

FIG. 2 is a schematic view of step S1, step S100 and step S200 of the method of manufacturing the red light-emitting chip carrying structure according to the present disclosure;

FIG. 3 is an enlarged view of part A of FIG. 2 according a certain embodiment of to the present disclosure;

FIG. 4 is another enlarged view of part A of FIG. 2 according another certain embodiment of to the present disclosure;

FIG. 5 is a schematic view of step S2 and step S102 of the method of manufacturing the red light-emitting chip carrying structure according to the present disclosure;

FIG. 6 is a schematic view of step S104 and step S104(A) of the method of manufacturing the red light-emitting chip carrying structure according to the present disclosure;

FIG. 7 is a schematic view of step S3 and step S106 of the method of manufacturing the red light-emitting chip carrying structure according to the present disclosure;

FIG. 8 is a schematic view of step S4 and step S108 of the method of manufacturing the red light-emitting chip carrying structure according to the present disclosure;

FIG. 9 is a schematic view of a red light-emitting chip carrying structure (after removing residual porous materials) according to a first embodiment of the present disclosure;

FIG. 10 is a schematic view of a position of each of the porous connection layers being detected by a detection device so as to obtain position information of each of the porous connection layers according to the first embodiment of the present disclosure;

FIG. 11 is a schematic view of step S2 and step S202 of the method of manufacturing the red light-emitting chip carrying structure according to the present disclosure;

FIG. 12 is a schematic view of step S204 and step S204(A) of the method of manufacturing the red light-emitting chip carrying structure according to the present disclosure;

FIG. 13 is a schematic view of step S3 and step S206 of the method of manufacturing the red light-emitting chip carrying structure according to the present disclosure;

FIG. 14 is a schematic view of step S4 and step S208 of the method of manufacturing the red light-emitting chip carrying structure according to the present disclosure;

FIG. 15 is a schematic view of a red light-emitting chip carrying structure (after removing residual porous materials) according to a second embodiment of the present disclosure;

FIG. 16 is a schematic view of a position of each of a plurality of conductive soldering materials being detected by a detection device so as to obtain position information of each of the conductive soldering materials according to the second embodiment of the present disclosure;

FIG. 17 is a schematic view of a position of each of the porous connection layers being detected by the detection device so as to obtain position information of each of the porous connection layers according to the second embodiment of the present disclosure; and

FIG. 18 is a schematic view of step S204(B) of the method of manufacturing the red light-emitting chip carrying structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

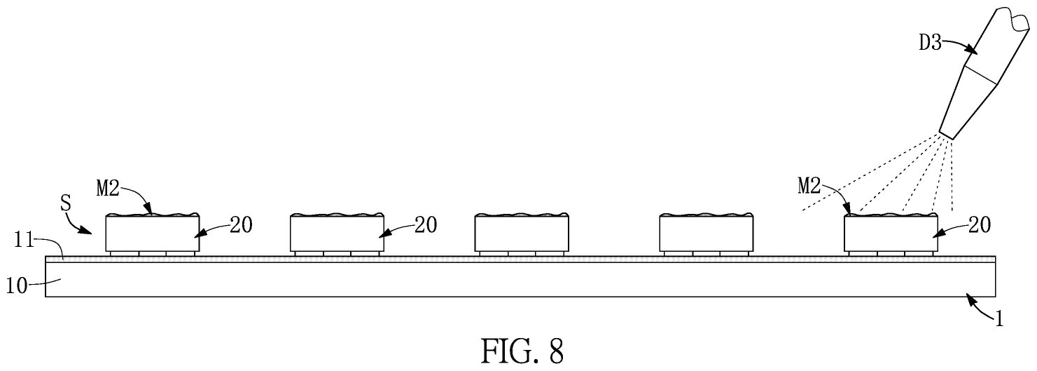

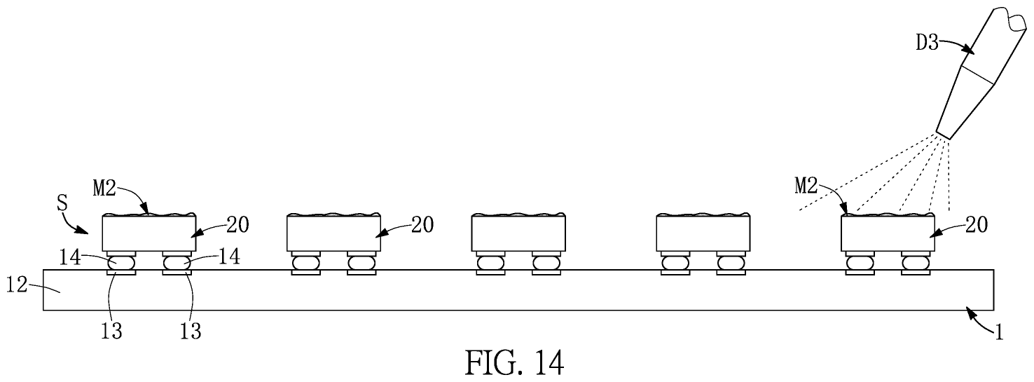

Referring to FIG. 8 or FIG. 14, the present disclosure provides a red light-emitting chip carrying structure S which includes a chip-carrying substrate 1 and a red light-emitting group 2. In addition, the red light-emitting group 2 includes a plurality of red light-emitting diode (LED) chips 20 disposed on the chip-carrying substrate 1, and each of the red LED chips 20 has a porous material (such as a residual part M2) remained on a top side thereof.

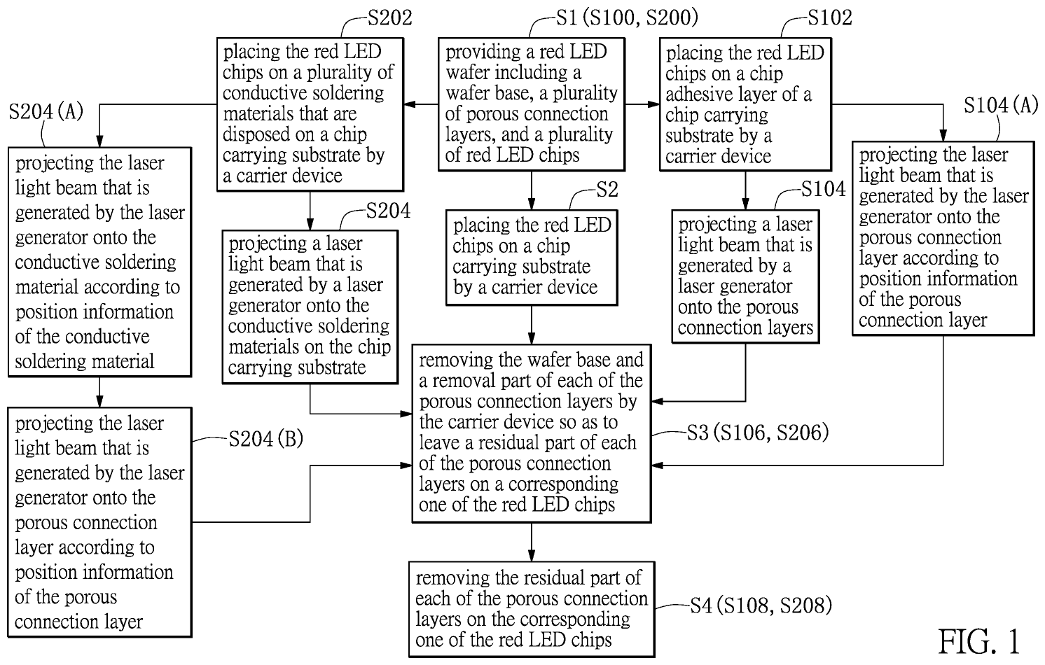

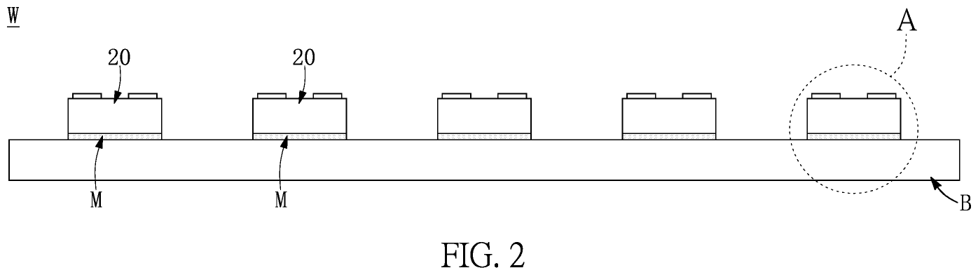

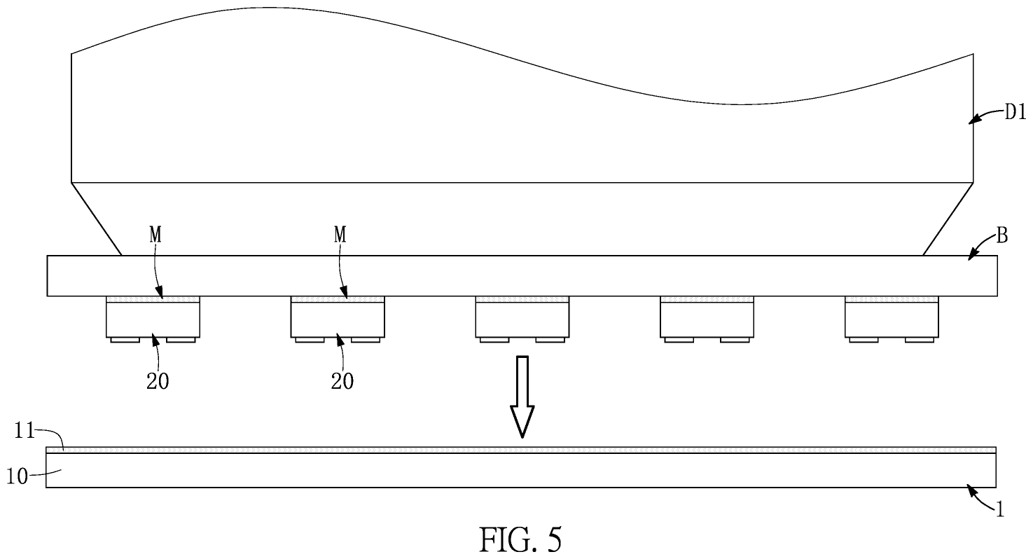

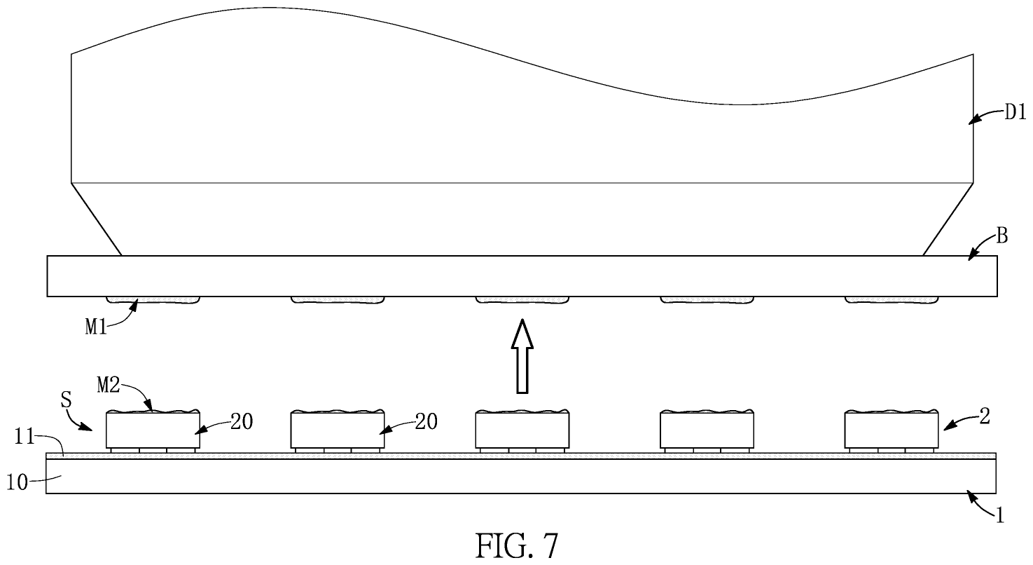

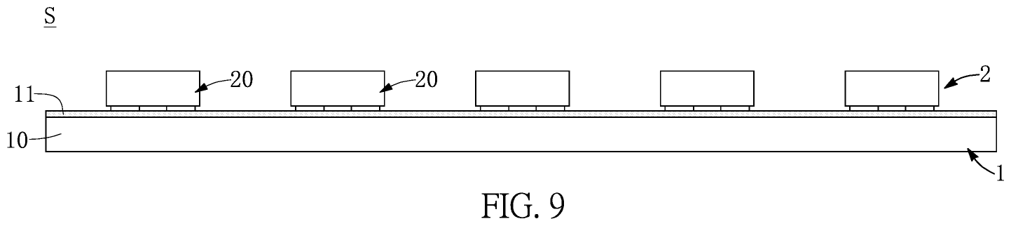

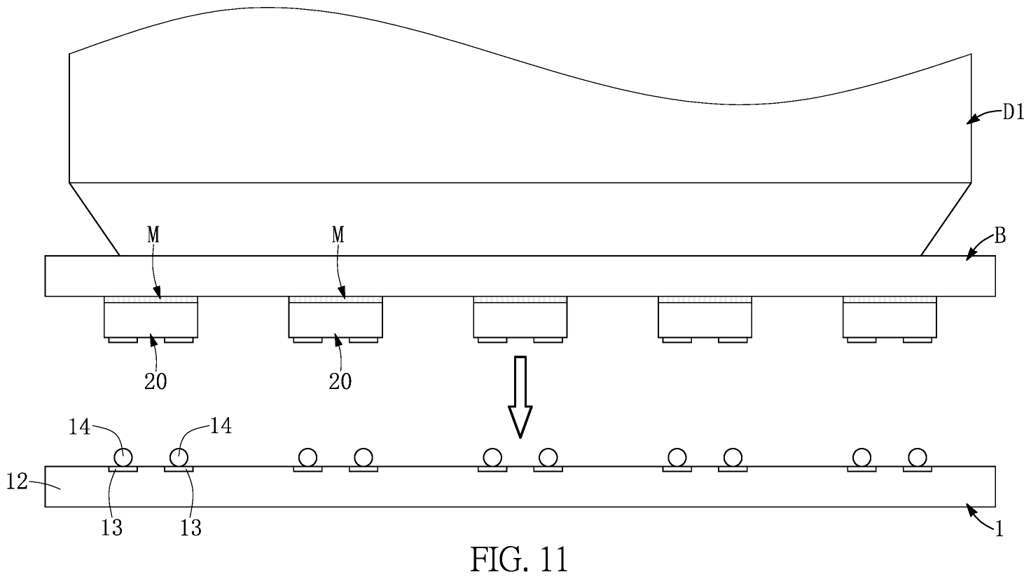

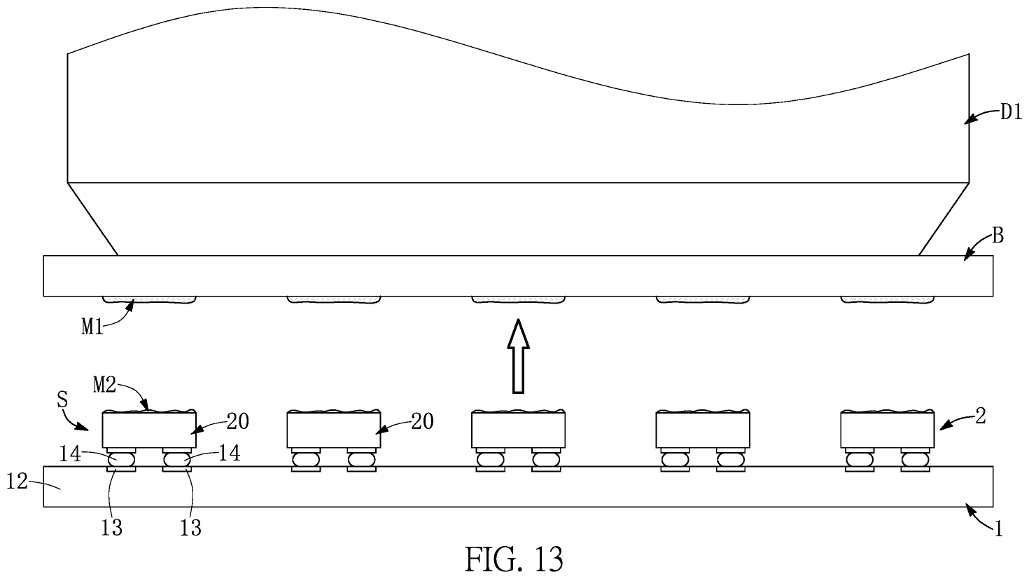

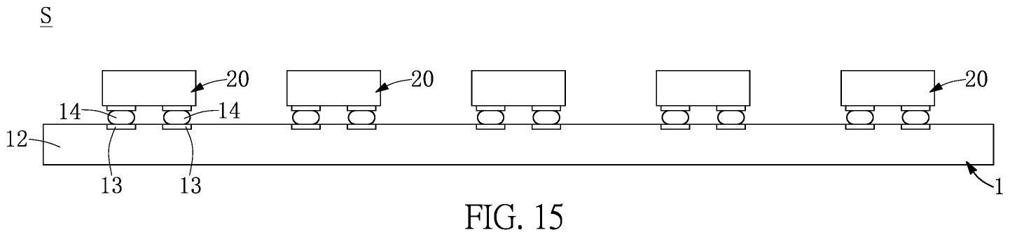

Referring to FIG. 1 to FIG. 18, the present disclosure provides a method of manufacturing a red light-emitting chip carrying structure S, which includes: firstly, referring to FIG. 1 and FIG. 2, providing a red LED wafer W including a wafer base B, a plurality of porous connection layers M disposed on the wafer base B, and a plurality of red LED chips 20 respectively disposed on the porous connection layers M (step S1); next, referring to FIG. 1 and FIG. 5 (or FIG. 11), placing the red LED chips 20 on a chip carrying substrate 1 by a carrier device D1 (step S2); afterwards, referring to FIG. 1 and FIG. 7 (or FIG. 13), removing the wafer base B and a removal part M1 (one part) of each of the porous connection layers M by the carrier device D1 so as to leave a residual part M2 (another part) of each of the porous connection layers M on a corresponding one of the red LED chips 20 (step S3); and then referring to FIG. 1, FIG. 8 and FIG. 9 (or FIG. 14 and FIG. 15), removing the residual part M2 of each of the porous connection layers M on the corresponding one of the red LED chips 20 (step S4).

### First Embodiment

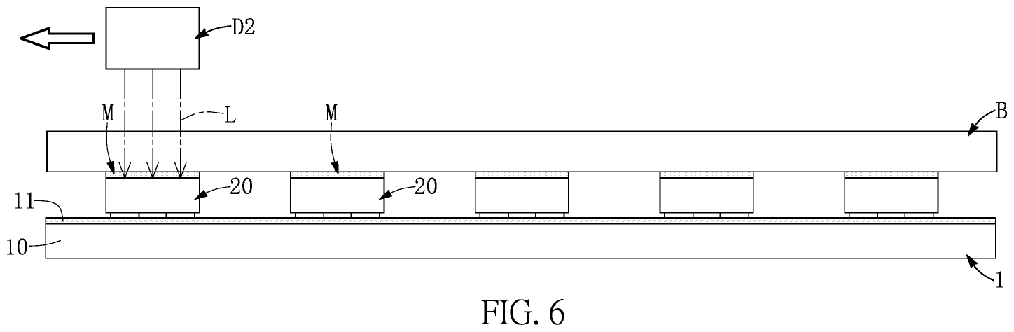

Referring to FIG. 1 to FIG. 10, a first embodiment of the present disclosure provides a method of manufacturing a red light-emitting chip carrying structure S, which includes: firstly, referring to FIG. 1 and FIG. 2, providing a red LED wafer W including a wafer base B, a plurality of porous connection layers M disposed on the wafer base B, and a plurality of red LED chips 20 respectively disposed on the porous connection layers M (step S100); next, referring to FIG. 1 and FIG. 5, placing the red LED chips 20 on a chip adhesive layer 11 of a chip carrying substrate 1 by a carrier device D1 (step S102); afterwards, referring to FIG. 1 and FIG. 6, projecting a laser light beam L that is generated by a laser generator D2 onto the porous connection layers M (step S104); subsequently, referring to FIG. 1 and FIG. 7, removing the wafer base B and a removal part M1 of each of the porous connection layers M by the carrier device D1 so as to leave a residual part M2 of each of the porous connection layers M on a corresponding one of the red LED chips 20 (step S106); and then referring to FIG. 1, FIG. 8 and FIG. 9, removing the residual part M2 of each of the porous connection layers M on the corresponding one of the red LED chips 20 by a removing device D3 (step S108). However, the aforementioned description is merely an example and is not meant to limit the scope of the present disclosure.

More particularly, referring to FIG. 2 and FIG. 7, the first embodiment of the present disclosure further provides a red light-emitting chip carrying structure S which includes a chip-carrying substrate 1 and a red light-emitting group 2. In addition, the red light-emitting group 2 includes a plurality of red LED chips 20 disposed on the chip-carrying substrate 1, and each of the red LED chips 20 has a porous material (such as a residual part M2) remained on a top side thereof. For example, the chip-carrying substrate 1 includes a chip-carrying body 10 and a chip adhesive layer 11 disposed on the chip-carrying body 10, and the red LED chips 20 are separately disposed on the chip adhesive layer 11 of the chip-carrying substrate 1. However, the aforementioned description is merely an example and is not meant to limit the scope of the present disclosure.

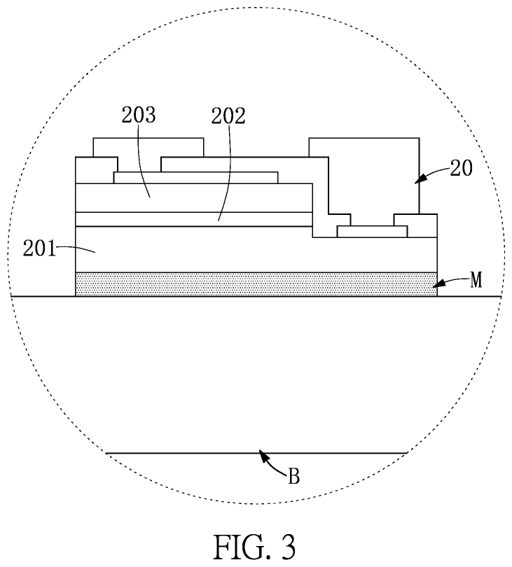

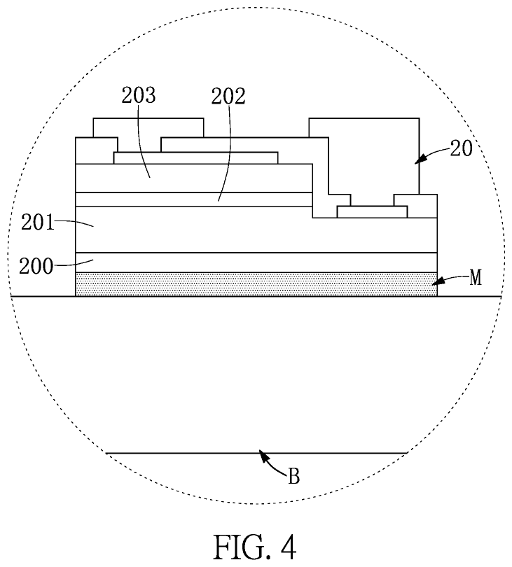

For example, as shown in FIG. 3, in a certain embodiment, the red LED chip 20 can be a micro LED chip without a base, and the micro LED chip includes a p-type semiconductor layer 201 contacting the porous connection layer M (or the porous material), a light-emitting layer 202 disposed on the p-type semiconductor layer 201, and an n-type semiconductor layer 203 disposed on the light-emitting layer 202. In addition, as shown in FIG. 4, in another certain embodiment, the red LED chip 20 can be a mini LED chip, and the mini LED chip includes a semiconductor base 200 contacting the porous connection layer M (or the porous material), a p-type semiconductor layer 201 disposed on the semiconductor base 200, a light-emitting layer 202 disposed on the p-type semiconductor layer 201, and an n-type semiconductor layer 203 disposed on the light-emitting layer 202. It should be noted that the porous material can be an oxide (such as an aluminum oxide, an arsenic oxide, a silicon oxide), a carbide, a nitride, a boride, a silicide, a silicon carbide, a polymer, or a graphene. However, the aforementioned description is merely an example and is not meant to limit the scope of the present disclosure.

For example, referring to FIG. 5 to FIG. 8, the carrier device D1 can be a chip-suction device (including a nozzle), a chip-clamping device, or any type of chip-carrying device. In addition, a wavelength of the laser light beam L that is generated by the laser generator D2 can be adjusted according to different situations and requirements. Moreover, the removing device D3 can be a cleaning device for providing an organic solvent or an inorganic solvent to clean out the porous material, or any material-removing device for removing the porous material. However, the aforementioned description is merely an example and is not meant to limit the scope of the present disclosure.

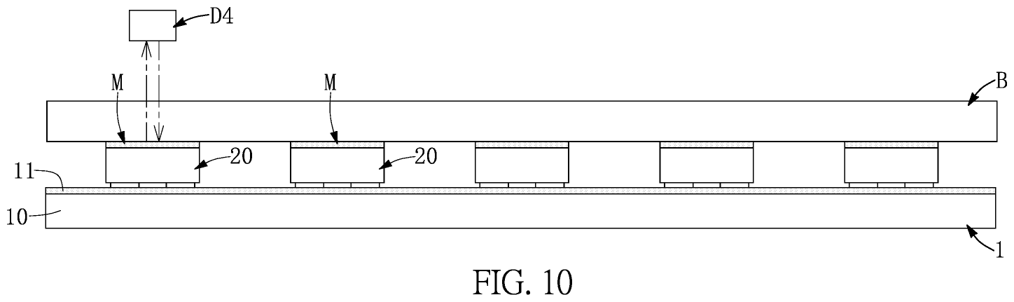

More particularly, referring to FIG. 1, FIG. 6 and FIG. 10, the step S104 of projecting the laser light beam L onto the porous connection layers M further includes: as shown in FIG. 6, projecting the laser light beam L that is generated by the laser generator D2 onto the porous connection layer M according to position information of the porous connection layer M (step S104(A)) so as to decrease a bonding strength of the porous connection layer M between the wafer base B and the red LED chip 20 (that is to say, the bonding strength (or a structural strength) of the porous connection layer M can be damaged by the laser light beam L). It should be noted that as shown in FIG. 10, a position of each of the porous connection layers M can be detected by a detection device D4 so as to obtain the position information of each of the porous connection layers M. In addition, referring to FIG. 6 and FIG. 7, by virtue of the laser light beam L that is generated by the laser generator D2, the bonding strength of the porous connection layer M between the wafer base B and the red LED chip 20 is smaller than a bonding strength between the red LED chip 20 and the chip adhesive layer 11 (as shown in FIG. 6), so that when the wafer base B and the removal part M1 of each of the porous connection layers M are removed, the red LED chips 20 can still definitely be adhered to the chip adhesive layer 11 (as shown in FIG. 7).

### Second Embodiment

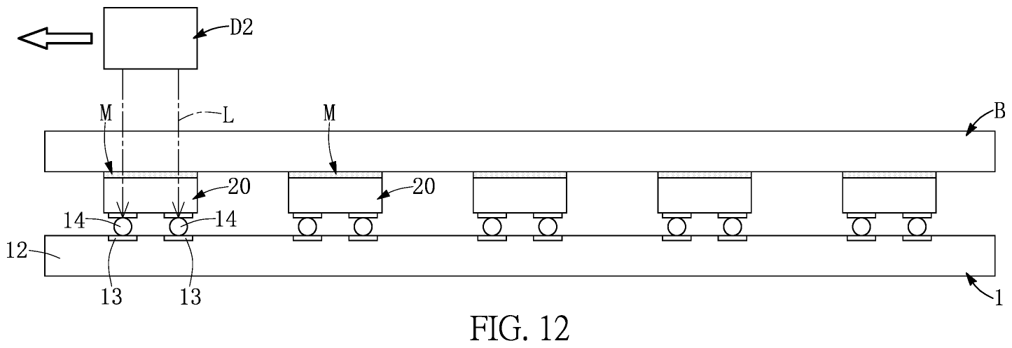

Referring to FIG. 1, and FIG. 11 to FIG. 18, a second embodiment of the present disclosure provides a method of manufacturing a red light-emitting chip carrying structure S, which includes: firstly, referring to FIG. 1 and FIG. 2, providing a red LED wafer W including a wafer base B, a plurality of porous connection layers M disposed on the wafer base B, and a plurality of red LED chips 20 respectively disposed on the porous connection layers M (step S200); next, referring to FIG. 1 and FIG. 11, placing the red LED chips 20 on a plurality of conductive soldering materials 14 that are disposed on a chip carrying substrate 1 by a carrier device D1 (step S202) (for example, before the step of 202, the conductive soldering materials 14 can be disposed on the chip carrying substrate 1 in advance, or the conductive soldering materials 14 can be disposed on the red LED chips 20 in advance); afterwards, referring to FIG. 1 and FIG. 12, projecting a laser light beam L that is generated by a laser generator D2 onto the conductive soldering materials 14 on the chip carrying substrate 1 (step S204); subsequently, referring to FIG. 1 and FIG. 13, removing the wafer base B and a removal part M1 of each of the porous connection layers M by the carrier device D1 so as to leave a residual part M2 of each of the porous connection layers M on a corresponding one of the red LED chips 20 (step S206); and then referring to FIG. 1, FIG. 14 and FIG. 15, removing the residual part M2 of each of the porous connection layers M on the corresponding one of the red LED chips 20 by a removing device D3 (step S208). However, the aforementioned description is merely an example and is not meant to limit the scope of the present disclosure.

More particularly, referring to FIG. 11 and FIG. 13, the second embodiment of the present disclosure further provides a red light-emitting chip carrying structure S which includes a chip-carrying substrate 1 and a red light-emitting group 2. In addition, the red light-emitting group 2 includes a plurality of red LED chips 20 disposed on the chip-carrying substrate 1, and each of the red LED chips 20 has a porous material (such as a residual part M2) remained on a top side thereof. For example, the chip-carrying substrate 1 includes a circuit substrate body 12, and a plurality of conductive soldering pads 13 disposed on the circuit substrate body 12, and the conductive soldering materials 14 are respectively disposed on the conductive soldering pads 13. In addition, each of the red LED chip 20 is disposed on corresponding two of the conductive soldering materials 14 so as to electrically connect to corresponding two of the conductive soldering pads 13, and the conductive soldering material 14 can be solder or any material for soldering. However, the aforementioned description is merely an example and is not meant to limit the scope of the present disclosure.

For example, in a certain embodiment, the red LED chip 20 can be a micro LED chip without a base, and the micro LED chip includes a p-type semiconductor layer contacting the porous connection layer M (or the porous material), a light-emitting layer disposed on the p-type semiconductor layer, and an n-type semiconductor layer disposed on the light-emitting layer. In addition, in another certain embodiment, the red LED chip 20 can be a mini LED chip, and the mini LED chip includes a semiconductor base contacting the porous connection layer M (or the porous material), a p-type semiconductor layer disposed on the semiconductor base, a light-emitting layer disposed on the p-type semiconductor layer, and an n-type semiconductor layer disposed on the light-emitting layer. It should be noted that the porous material can be an oxide (such as an aluminum oxide, an arsenic oxide, a silicon oxide), a carbide, a nitride, a boride, a silicide, a silicon carbide, a polymer, or a graphene. However, the aforementioned description is merely an example and is not meant to limit the scope of the present disclosure.

For example, referring to FIG. 11 to FIG. 18, the carrier device D1 can be a chip-suction device (including a nozzle), a chip-clamping device, or any type of chip-carrying device. In addition, a wavelength of the laser light beam L that is generated by the laser generator D2 can be adjusted according to different situations and requirements. Moreover, the removing device D3 can be a cleaning device for providing an organic solvent or an inorganic solvent to clean out the porous material, or any material-removing device for removing the porous material. However, the aforementioned description is merely an example and is not meant to limit the scope of the present disclosure.

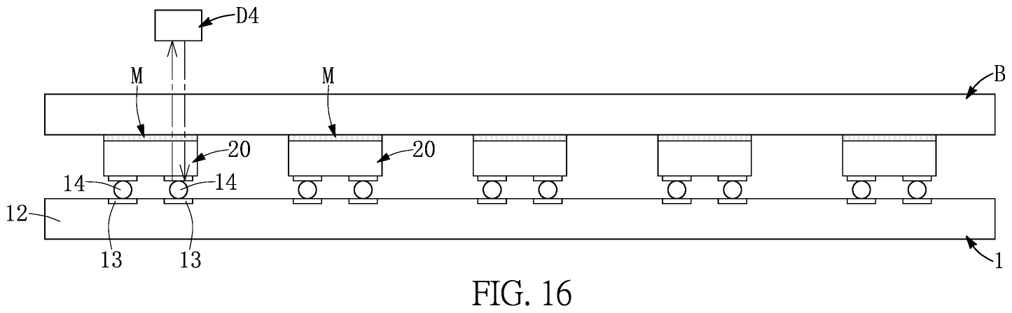

More particularly, referring to FIG. 1, FIG. 12 and FIG. 16, the step S204 of projecting the laser light beam L onto the conductive soldering material 14 further includes: as shown in FIG. 12, projecting the laser light beam L that is generated by the laser generator D2 onto the conductive soldering material 14 according to position information of the conductive soldering material 14 (step S204(A)) so as to increase a bonding strength between the red LED chip 20 and the conductive soldering material 14 (that is to say, when each of the red LED chips 20 are bonded on the corresponding two of the conductive soldering material 14, the bonding strength between the red LED chip 20 and the conductive soldering material 14 can be increased through the laser light beam L). It should be noted that as shown in FIG. 16, a position of each of a plurality of conductive soldering materials 14 can be detected by a detection device D4 so as to obtain the position information of each of the conductive soldering materials 14. In addition, referring to FIG. 12 and FIG. 13, by virtue of the laser light beam L that is generated by the laser generator D2, the bonding strength between the red LED chip 20 and the conductive soldering material 14 is larger than a bonding strength of the porous connection layer M between the wafer base B and the red LED chip 20 (as shown in FIG. 12), so that when the wafer base B and the removal part M1 of each of the porous connection layers M are removed, each of the red LED chips 20 is still definitely bonded on the corresponding two of the conductive soldering materials 14 (as shown in FIG. 13).

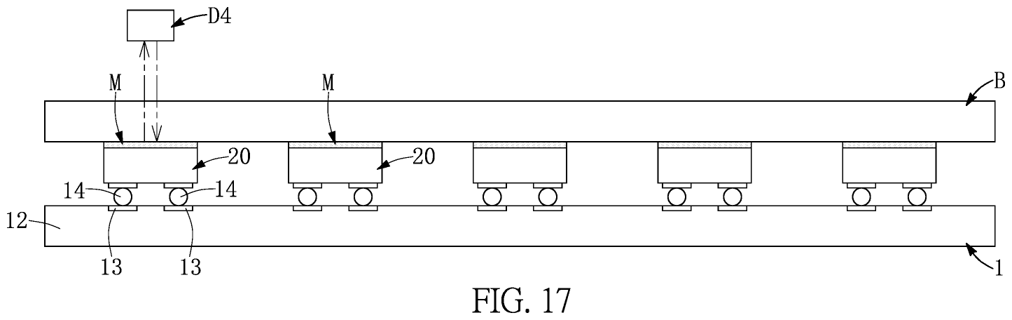

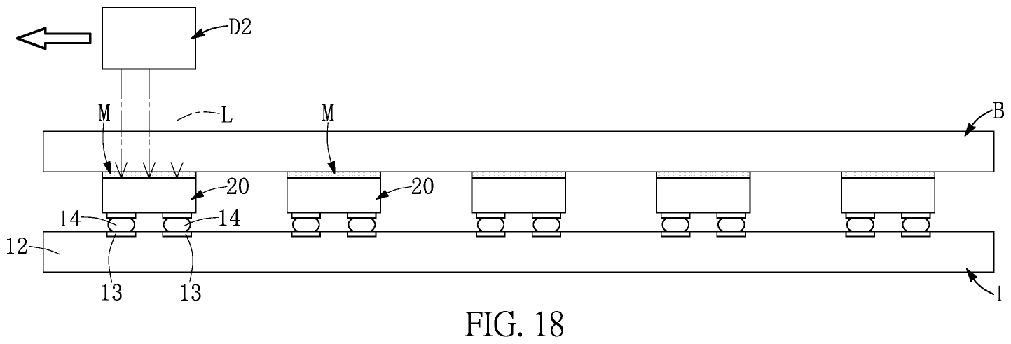

It should be noted that referring to FIG. 13, FIG. 17, and FIG. 18, after the step S204(A), the method of the second embodiment further includes: as shown FIG. 18, projecting the laser light beam L that is generated by the laser generator D2 onto the porous connection layer M according to position information of the porous connection layer M (step S204(B)) so as to decrease a bonding strength of the porous connection layer M between the wafer base B and the red LED chip 20 (that is to say, the bonding strength (or a structural strength) of the porous connection layer M can be damaged by the laser light beam L). It should be noted that as shown in FIG. 17, a position of each of the porous connection layers M can be detected by a detection device D4 so as to obtain the position information of each of the porous connection layers M. In addition, referring to FIG. 12, FIG. 13 and FIG. 18, by virtue of the laser light beam L that is generated by the laser generator D2, the bonding strength of the porous connection layer M between the wafer base B and the red LED chip 20 is smaller than a bonding strength between the red LED chip 20 and the corresponding two of the conductive soldering materials 14 (as shown in FIG. 12 and FIG. 18), so that when the wafer base B and the removal part M1 of each of the porous connection layers M are removed, each of the red LED chips 20 is still definitely bonded on the corresponding two of the conductive soldering materials 14 (as shown in FIG. 13).

### BENEFICIAL EFFECTS OF THE EMBODIMENTS

In conclusion, by virtue of “placing the red LED chips 20 on a chip carrying substrate 1” and “removing the wafer base B and a removal part M1 of each of the porous connection layers M so as to leave a residual part M2 of each of the porous connection layers M on a corresponding one of the red LED chips 20”, the red LED chips 20 can be transferred from the red LED wafer W to a chip adhesive layer 11 of the chip carrying substrate 1 or a plurality of conductive soldering materials 14 on the chip carrying substrate 1.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method of manufacturing a red light-emitting chip carrying structure, comprising:
providing a red light-emitting diode (LED) wafer including a wafer base, a plurality of porous connection layers disposed on the wafer base, and a plurality of red LED chips respectively disposed on the porous connection layers;
placing the red LED chips on a chip carrying substrate;
projecting a laser light beam onto the porous connection layers or the chip carrying substrate; and
removing the wafer base and a removal part of each of the porous connection layers so as to leave a residual part of each of the porous connection layers on a corresponding one of the red LED chips.

2. The method according to claim 1, wherein the step of projecting the laser light beam onto the porous connection layers further comprises:
detecting a position of each of the porous connection layers so as to obtain position information of each of the porous connection layers; and
projecting the laser light beam onto the porous connection layer according to the position information of the porous connection layer so as to decrease a bonding strength of the porous connection layer between the wafer base and the red LED chip.

3. The method according to claim 2, wherein the chip-carrying substrate includes a chip-carrying body and a chip adhesive layer disposed on the chip-carrying body, and the red LED chips are separately disposed on the chip adhesive layer of the chip-carrying substrate.

4. The method according to claim 3, wherein the bonding strength of the porous connection layer between the wafer base and the red LED chip is smaller than a bonding strength between the red LED chip and the chip adhesive layer, so that when the wafer base and the removal part of each of the porous connection layers are removed, the red LED chips are still adhered to the chip adhesive layer.

5. The method according to claim 1, wherein the step of projecting the laser light beam onto the chip carrying substrate further comprises:
detecting a position of each of a plurality of conductive soldering materials so as to obtain position information of each of the conductive soldering materials; and
projecting the laser light beam onto the conductive soldering material according to the position information of the conductive soldering material so as to increase a bonding strength between the red LED chip and the conductive soldering material.

6. The method according to claim 5, wherein the chip-carrying substrate includes a circuit substrate body, and a plurality of conductive soldering pads disposed on the circuit substrate body, the conductive soldering materials are respectively disposed on the conductive soldering pads, and each of the red LED chip is disposed on corresponding two of the conductive soldering materials so as to electrically connect to corresponding two of the conductive soldering pads.

7. The method according to claim 6, wherein the bonding strength between the red LED chip and the conductive soldering material is larger than a bonding strength of the porous connection layer between the wafer base and the red LED chip, so that when the wafer base and the removal part of each of the porous connection layers are removed, each of the red LED chips is still bonded on the corresponding two of the conductive soldering materials.

8. The method according to claim 1, wherein the step of projecting the laser light beam onto the chip carrying substrate or the chip carrying substrate further comprises:
detecting a position of each of a plurality of conductive soldering materials so as to obtain position information of each of the conductive soldering materials;
projecting the laser light beam onto the conductive soldering material according to the position information of the conductive soldering material so as to increase a bonding strength between the red LED chip and the conductive soldering material;
detecting a position of each of the porous connection layers so as to obtain position information of each of the porous connection layers; and
projecting the laser light beam onto the porous connection layer according to the position information of the porous connection layer so as to decrease a bonding strength of the porous connection layer between the wafer base and the red LED chip.

9. The method according to claim 8, wherein the chip-carrying substrate includes a circuit substrate body, and a plurality of conductive soldering pads disposed on the circuit substrate body, the conductive soldering materials are respectively disposed on the conductive soldering pads, and each of the red LED chip is disposed on corresponding two of the conductive soldering materials so as to electrically connect to corresponding two of the conductive soldering pads.

10. The method according to claim 9, wherein the bonding strength of the porous connection layer between the wafer base and the red LED chip is smaller than a bonding strength between the red LED chip and the corresponding two of the conductive soldering materials, so that when the wafer base and the removal part of each of the porous connection layers are removed, each of the red LED chips is still bonded on the corresponding two of the conductive soldering materials.

11. The method according to claim 1, wherein, after the step of removing the wafer base and the removal part of each of the porous connection layers, the method further comprises: removing the residual part of each of the porous connection layers on the corresponding one of the red LED chips.
